(19) United States
(12) Patent Application Publication
(10) Pub. No.: US 2015/0054172 A1
(43) Pub. Date: Feb. 26, 2015

(54) SEMICONDUCTOR DEVICE AND METHOD OF MANUFACTURING THE SAME

(71) Applicant: KABUSHIKI KAISHA TOSHIBA, TOKYO (JP)

(72) Inventors: Takashi SHIRONO, Oita (JP); Kazuyuki HIGASHI, Oita (JP); Shinya WATANABE, Oita (JP); Tatsuo MIGITA, Oita (JP)

(73) Assignee: KABUSHIKI KAISHA TOSHIBA, TOKYO (JP)

(21) Appl. No.: 14/194,776

(22) Filed: Mar. 2, 2014

(30) Foreign Application Priority Data
Aug. 21, 2013 (JP) 2013-171746

(51) Int. Cl. H01L 23/498; H01L 21/768

(52) U.S. Cl. CPC H01L 23/49827; H01L 21/76877
USPC 257/774; 438/667

(57) ABSTRACT

According to one embodiment, a semiconductor device includes an integrated circuit and a conductive material. The integrated circuit is provided on a surface of a semiconductor layer. The conductive material is embedded into a via which penetrates the semiconductor layer in a thickness direction thereof and is electrically connected to the integrated circuit. The conductive material includes a contact portion and a through portion, and the contact portion includes a cross-sectional area that is greater than a cross-sectional area of the through portion.

### CROSS-REFERENCE TO RELATED APPLICATION

This application is based upon and claims the benefit of priority from Japanese Patent Application No. 2013-171746, filed Aug. 21, 2013, the entire contents of which are incorporated herein by reference.

### FIELD

Embodiments described herein relate generally to a semiconductor device and a method of manufacturing the same.

### BACKGROUND

Conventionally, there exists a technique of reducing the surface area of a semiconductor device by stacking a plurality of semiconductor chips, with integrated circuits formed thereon, and electrically connecting the semiconductor chips together with a Through Silicon Via (TSV). The TSV is formed by boring such as by etching, forming a through-hole in a thickness direction of a semiconductor layer with the integrated circuit formed on one surface thereof. The TSV includes an embedded conductive material that electrically connects to the integrated circuit through the substrate.

Due to miniaturization of semiconductor chips and the high degree of integration of the integrated circuit, the TSV tends to have a reduced cross sectional area (e.g., diameter in the case of a circular cross-section). Due to this reduced cross section of the TSV, a contact resistance between the TSV and the integrated circuit is disadvantageously increased.

### BRIEF DESCRIPTION OF THE DRAWINGS

FIG. 1 is a cross-sectional schematic diagram showing a semiconductor device according to an embodiment.

FIGS. 2A, 2B, and 2C are cross-sectional schematic diagrams each showing the manufacturing process of the semiconductor device according to the embodiment.

FIGS. 3A, 3B, and 3C are cross-sectional schematic diagrams each showing the manufacturing process of the semiconductor device according to the embodiment.

FIGS. 4A, 4B and 4C are cross-sectional schematic diagrams each showing the manufacturing process of the semiconductor device according to the embodiment.

FIGS. 5A and 5B are cross-sectional schematic diagrams each showing the manufacturing process of the semiconductor device according to the embodiment.

### DETAILED DESCRIPTION

In general, according to one embodiment, there is provided a semiconductor device capable of reducing the contact resistance between the TSV and the integrated circuit and a method of manufacturing the same.

According to one embodiment, there is provided a semiconductor device that includes an integrated circuit and a conductive material. The integrated circuit is provided on or adjacent to one surface of a semiconductor layer. The conductive material is embedded into a via which penetrates the semiconductor layer in a thickness direction of the semiconductor layer and is electrically connected to the integrated circuit. The conductive material includes a contact portion in contact with the integrated circuit that has a cross-sectional area that is greater than a cross-sectional area of a through portion of the conductive material penetrating the semiconductor layer.

Hereinafter, with reference to the attached drawings, a semiconductor device and a method of manufacturing the same according to the embodiment will be described in detail. Here, the embodiment is not to restrict the disclosure.

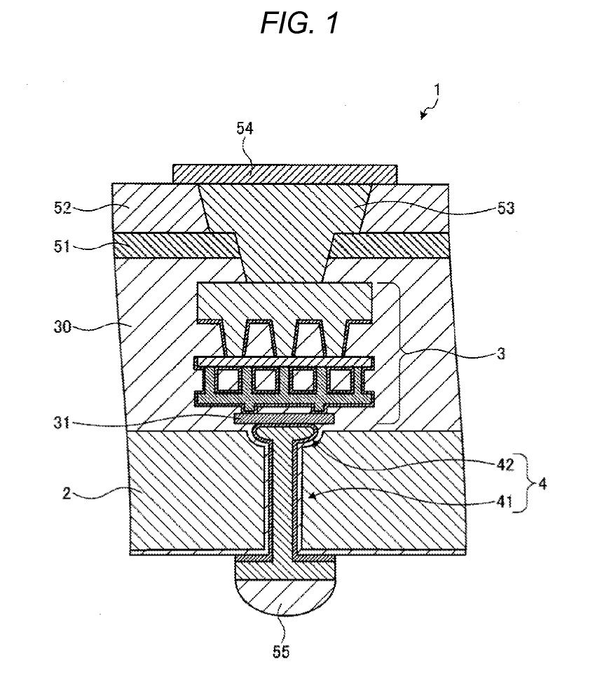

FIG. 1 is a cross-sectional schematic diagram showing a semiconductor device according to the embodiment. As illustrated in FIG. 1, a semiconductor device 1 according to the embodiment is provided with an integrated circuit 3 formed on or within one surface (hereinafter, described as “surface”) of a semiconductor layer 2 of, for example, a silicon wafer and a via 4 bored in the semiconductor layer 2 in a thickness direction thereof from an opposite surface of the semiconductor layer to connect with the integrated circuit 3.

The integrated circuit 3 is provided within an interlayer insulating film 30 formed on the surface of the semiconductor layer 2. The interlayer insulating film 30 is formed of, for example, silicon oxide. The integrated circuit 3 is, for example, a Large Scale Integration (LSI) device including a semiconductor memory and multilayer wiring. FIG. 1 selectively shows a portion of the multilayer wiring in the integrated circuit 3.

Further, on the surface of the integrated circuit 3, a passivation film 51 and a protective film 52 are stacked. The passivation film 51 is formed of, for example, silicon oxide or silicon nitride. The protective film 52 is formed of resin such as polyethylene terephthalate (PET) or polyimide.

An upper electrode pad 54 is provided on the surface of the protective film 52 at a predetermined position. The upper electrode pad 54 is formed of, for example, gold. The upper electrode pad 54 and the integrated circuit 3 are connected through an upper electrode 53 which penetrates the protective film 52, the passivation film 51, and the interlayer insulating film 30 to connect to the integrated circuit 3. The upper electrode 53 is formed of, for example, nickel.

A via 4 is provided which penetrates the semiconductor layer 2, and when the semiconductor device 1 is stacked in a multiple stages, the via 4 is a through electrode (TSV: Through Silicon Via) for electrically connecting the integrated circuit 3 of the semiconductor device 1 in a lower chip to the integrated circuit 3 of the semiconductor device 1 in a chip located thereover. This via 4 is formed of, for example, copper.

A bump 55 for electrically connecting to the upper electrode pad 54 of a lower semiconductor device chip (not shown) is provided on the rear side of the semiconductor layer 2, about the via 4. The bump 55 is formed of, for example, solder.

Here, the general configuration of the via is a cylindrical conductive material which penetrates the semiconductor layer. Due to progression of miniaturization of the semiconductor device and large scale integration of the integrated circuit, the diameter of the cylindrical via gets smaller and the contact area with the integrated circuit is decreased, thereby increasing a contact resistance with the integrated circuit.

The via 4 according to the embodiment is formed so that the cross section of the contact portion 42 thereof with the integrated circuit 3 in a direction normal to the thickness direction of the semiconductor layer 2 is larger than the cross section of the penetrating through portion 41 in a direction normal to the thickness direction of the semiconductor layer 2.

By employing this via 4, even when the through portion 41 is scaled to a smaller size (due to the miniaturization of the semiconductor device 1 and large scale integration of the integrated circuit 3), the contact portion 42, having a larger cross section than that of the through portion 41, can assure a reliable and large area of contact with the integrated circuit 3, thereby reducing a contact resistance between the integrated circuit 3 and the via 4.

Further, the contact portion 42 of the via 4 is formed in a shape that expands from the upper end of the through portion 41 in a direction that is parallel to the surface of the semiconductor layer 2. When a tension is applied to the via 4, the greater cross-sectional area of the contact portion 42 resists the tension. Therefore, according to the via 4, improved resistance against tension, and against separation of the via and the integrated circuit 3, is provided.

Further, in the integrated circuit 3 included in the semiconductor device 1 a metal silicide is used for a contact pad 31 that connects the integrated circuit with the via 4. By employing this structure, in the process of forming the via 4, when the through-hole penetrating the semiconductor layer 2 is formed by etching, the contact portion 31 can serve as an etch stopper. Accordingly, when the through-hole for forming the via 4 is formed, overetching of the via 4 into the semiconductor device 1 can be avoided.

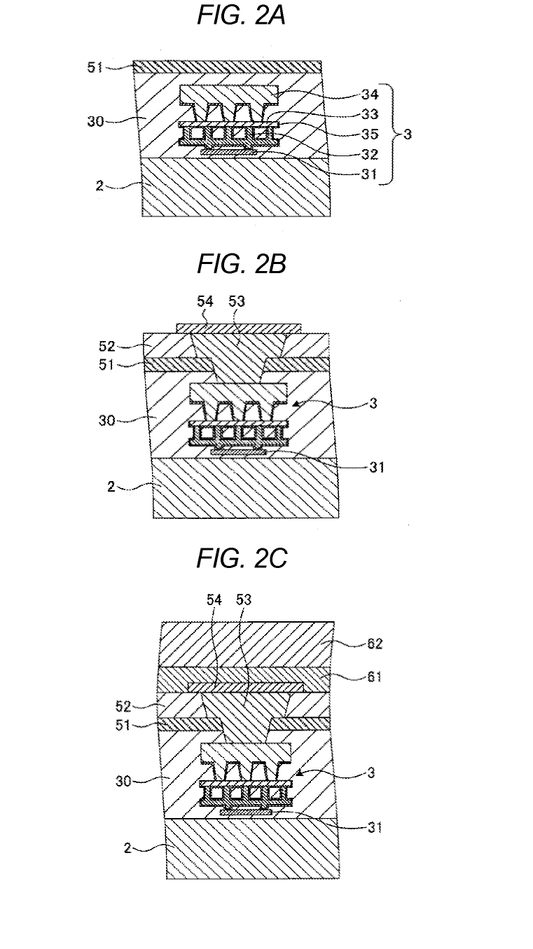

Next, with reference to FIGS. 2A to 5B, the manufacturing process of the semiconductor device 1 according to the embodiment will be described. FIGS. 2A to 5B are cross-sectional schematic diagrams each for describing the manufacturing process of the semiconductor device 1 according to the embodiment.

In manufacturing the semiconductor device 1, the integrated circuit 3 is formed on the surface of the semiconductor layer 2, as illustrated in FIG. 2A. For example, when forming the multilayer wiring of the integrated circuit 3, a silicon oxide film is formed on the surface of the semiconductor layer 2, a concave portion for forming the contact pad 31 is formed on the silicon oxide film through photolithography, and polysilicon is embedded in the concave portion. Thereafter, a nickel layer is formed on the polysilicon and heated, and a nickel silicide contact pad 31 is formed.

Here, the material of the contact pad 31 is not restricted to nickel silicide but may be any metal that can be used as an etch stop material, i.e., one that is not significantly etched by the etchant used to form the via 4. An example includes tungsten, or any metal silicide.

Then, the process of forming a silicon oxide film, the process of patterning the silicon oxide film through photolithography, and the process of covering a concave portion of the wiring pattern formed by the patterning with a barrier metal to embed the conductive material will be sequentially repeated.

According to this, a first wiring layer 32, a second wiring layer 33, and a third wiring layer 34 whose interface with the interlayer insulating film 30 is covered with a barrier metal 35 are formed within the interlayer insulating film 30. Thereafter, the passivation film 51 using, for example, silicon oxide or silicon nitride is formed on the upper surface of the interlayer insulating film 30.

Here, for example, tungsten is used for the first wiring layer 32. For example, copper is used for the second wiring layer 33 and aluminum is used for the third wiring layer 34. As far as it is a conductive material, any metal other than the above-mentioned metals may be used respectively for the first wiring layer 32, the second wiring layer 33, and the third wiring layer 34.

Further, for example, titanium nitride or nickel nitride is used for the barrier metal 35. As for the barrier metal 35, any material other than the above-mentioned ones may be used, as long as the metal prevents diffusion of the conductive material from the first wiring layer 32, the second wiring layer 33, and the third wiring layer 34 to the interlayer insulating film 30.

Subsequently, after the protective film 52 is formed by using resin such as PET or polyimide on the upper surface of the passivation film 51, a through-hole is formed to penetrate the protective film 52, the passivation film 51, and the interlayer insulating film 30 to reach the integrated circuit 3. Then, as illustrated in FIG. 2B, the through-hole is embedded with, for example, nickel, hence to form the upper electrode 53. Here, any conductive metal other than nickel may be used for the upper electrode 53.

Then, the upper electrode pad 54 is formed by using, for example, aluminum on the exposed surface on the top of the upper electrode 53. Here, any conductive metal other than aluminum may be used for the upper electrode pad 54.

Then, as illustrated in FIG. 2C, after an adhesive agent 61 is applied on the upper surface of the upper electrode pad 54 and the protective film 52, a supporting substrate 62 is attached to the upper surface of the adhesive agent 61. For the supporting substrate 62, for example, a silicon substrate or a glass substrate is used.

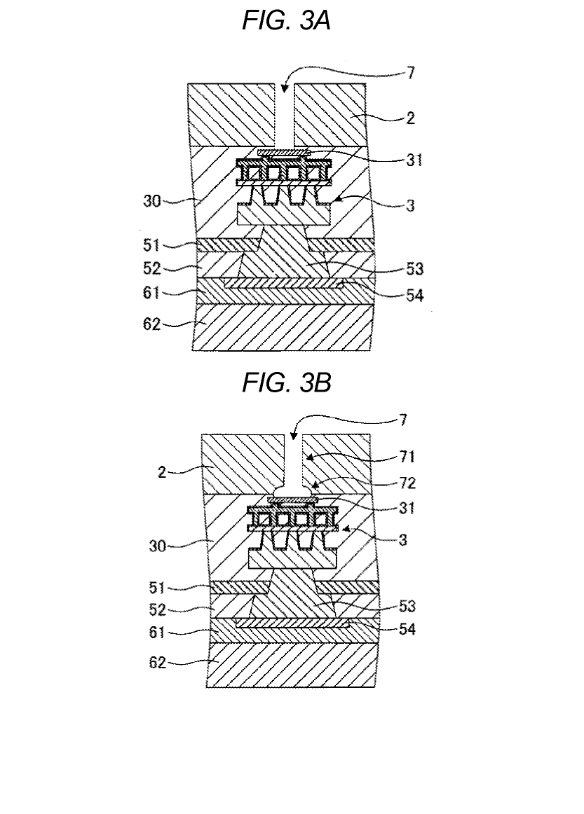

Then, as illustrated in FIG. 3A, the structure shown in FIG. 2C is set upside down and a through-hole 7 penetrating the semiconductor layer 2 from the rear surface of the semiconductor layer 2 in the thickness direction and reaching the contact pad 31 of the integrated circuit 3 is formed.

This through-hole 7 is formed, for example, by performing anisotropic plasma etching (hereinafter, referred to “first etching”) from the rear surface of the semiconductor layer 2 toward the contact pad 31. Here, as mentioned above, since the contact pad 31 is formed of nickel silicide so that the contact pad 31 may be utilized as the etch stop layer, the through-hole 7 terminates at the upper surface of the contact pad 31. Alternatively, in order to reduce the etching in the first etching, the rear surface of the semiconductor layer 2 may be ground to reduce the thickness of the semiconductor layer 2 before the first etching step is performed.

Subsequently, as illustrated in FIG. 3B, an expanded portion 72 of the through-hole 7 having a hemispherical profile and interfacing with the integrated circuit 3 is formed. The expanded portion may have many different shapes, including generally flat and circular, rectangular, elliptical or the like, so long as an outer perimeter thereof is larger than the perimeter of the main portion of the via 71. More specifically, the expanded portion 72 is formed by performing another plasma etching (hereinafter, referred to a “second etching” step) different from the processing conditions of the first etching step.

For example, in the second etching step, a bias voltage for accelerating ions to collide with an etching target is set greater than the bias voltage in the first etching. Alternatively, in the second etching, the concentration of the etchant gas is set greater than the concentration of the etchant gas in the first etching. Alternatively, in the second etching, the ion energy of the plasma etchant gas is set greater than the ion energy of the plasma etchant gas in the first etching, or the ratio of the etchant gases is changed. Further, in the second etching step, etching is performed for a longer time period than the etching time period in the first etching step.

Of the several above-mentioned changes in processing conditions, any one or some are performed, hence to make it difficult to etch further in the thickness direction of the semiconductor layer 2 in the expanded portion 72 of the through-hole 7, and to make it possible to etch in the direction parallel to the surface direction of the semiconductor layer 2.

Using such processes, the expanded portion 72 is formed so that the cross section of the expanded portion 72 of the through-hole 7 extending in the direction normal to the thickness direction of the semiconductor layer 2 becomes larger than the cross section of the through portion 71 of the via 4 penetrating the semiconductor layer 2 extending in the direction normal to the thickness direction of the semiconductor layer 2. After the expanded portion 72 is formed, as illustrated in FIG. 3C the inner peripheral surface of the through-hole 7 and the rear surface of the semiconductor layer 2 are covered with an oxide film 81.

As mentioned above, after the first etching step, the process conditions of etching has only to be changed to perform the second etching using the same processor (chamber) that the first etching step was performed in. As a result, the through-hole 7 having a shape as shown in FIG. 3B is formed.

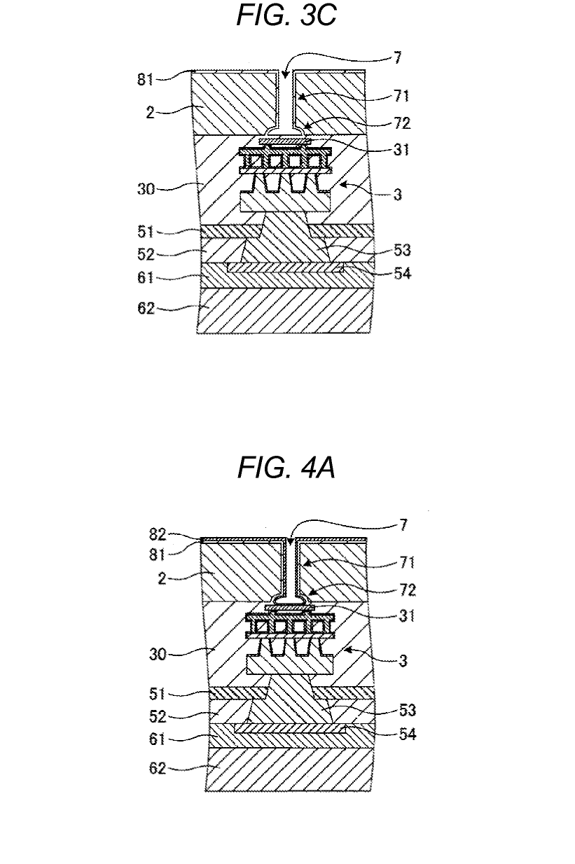

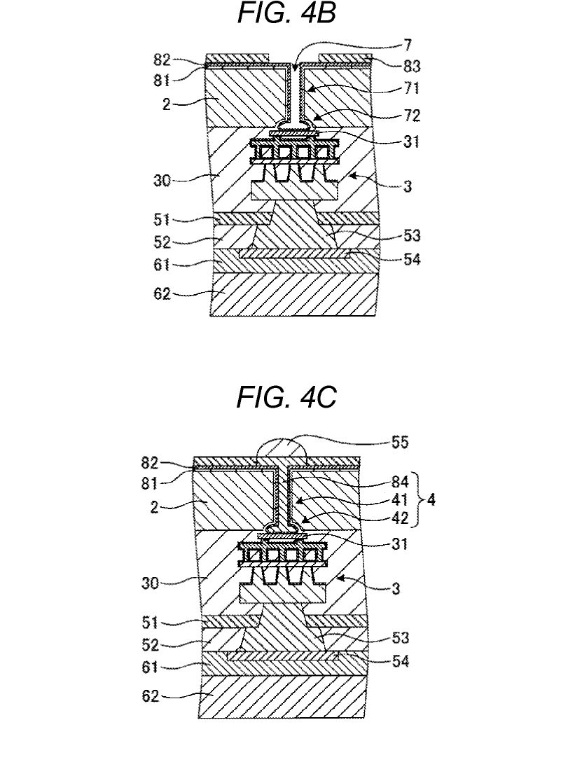

Subsequently, as illustrated in FIG. 4A, by removing the oxide film. 81 from the bottom of the through-hole 7 by etching, the upper surface of the contact pad 31 is exposed and thereafter, the inner peripheral surface of the through-hole 7 and the rear surface of the semiconductor layer 2 are covered with a barrier metal 82.

The barrier metal 82 is formed by using, for example, a titanium nitride film or a nickel nitride film by sputtering. Here, the barrier metal 82 may be formed of any material other than the above-mentioned materials as long as the material is capable of preventing the metal embedded in the through-hole 7 from diffusing into the semiconductor layer 2.

Then, as illustrated in FIG. 4B, a resist 83 is applied to the rear surface of the semiconductor layer 2 covered with the barrier metal 82, and the resist 83 is patterned through photolithography. Here, the resist 83 is patterned so that a hole having a larger opening area than that of the through-hole 7 may be formed at the opening position of the through-hole 7 on the rear surface of the semiconductor layer 2.

Subsequently, as illustrated in FIG. 4C, the via 4 is formed by embedding a conductive material 84 into the through-hole 7. For the conductive material 84, for example, copper is used. The via 4 is formed through sputtering or plating.

Following these steps, the via 4 is formed so that the cross section of the contact portion 42 with the integrated circuit 3 extending in the direction normal to the thickness direction of the semiconductor layer 2 is greater than the cross section of the through portion 41 penetrating the semiconductor layer 2 extending in the direction normal to the thickness direction of the semiconductor layer 2. Thereafter, the bump 55 electrode is formed, for example, by soldering, on the upper surface of the rear side of the semiconductor layer 2 around the via 4.

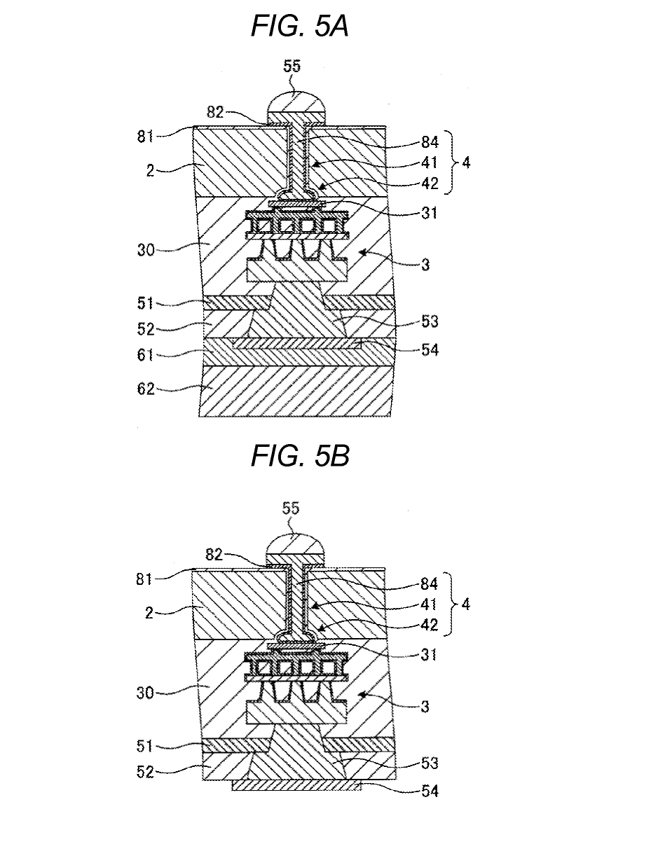

Subsequently, as illustrated in FIG. 5A, the resist 83 and the barrier metal 82 under the resist 83 are removed, and further, as illustrated in FIG. 5B, the supporting substrate 62 and the adhesive agent 61 are removed. Then, by setting the structure shown in FIG. 5B upside down, the semiconductor device 1 shown in FIG. 1 is formed. Here, the semiconductor device 1 is diced into individual die or chips from a substrate, and the die are stacked one above the other and interconnected by flowing of the solder bumps 55 of one die to connect the solder to the upper electrode pad 54 of the adjacent die, and the stack of die are over-molded with resin, to obtain a packaged multi-die or multi-chip product.

As mentioned above, the semiconductor device according to the embodiment is provided with a via penetrating the semiconductor layer and connected to the integrated circuit thereof. The via is formed so that the cross-sectional size of the contact portion with the integrated circuit extending in the direction normal to the thickness direction of the semiconductor layer is greater than the cross-sectional size of the through portion penetrating the semiconductor layer extending in the direction normal to the thickness direction of the semiconductor layer. Therefore, the semiconductor device according to the embodiment can reduce the contact resistance between the via and the integrated circuit because the contact area of the via and internal electrode 31 is enlarged compared to the remainder of the via size.

Further, when tension is applied to the via in the semiconductor device according to the embodiment, the contact portion with the integrated circuit in the via serves as a cleat or anchor in the semiconductor layer 2. Therefore, the via according to the embodiment can improve resistance to tension and the likelihood of separation of the via 4 and the underlying electrode 31.

In the above-mentioned embodiment, although the cross sectional shape of the through portion 41 and the contact portion 42 in the via 4 in the direction normal to the thickness direction of the semiconductor layer 2 has not been particularly specified, the cross sectional shape of the via 4 may be circular, rectangular, or elliptical.

In the above-mentioned embodiment, while the size of the bump 55 is larger than the cross section of the through portion 41 of the via 4 in the direction normal to the thickness direction of the semiconductor layer 2 has been described, the size of the bump 55 may be reduced to the size of the through portion 41. According to this, the surface area of the bump 55 on the rear surface of the semiconductor layer 2 can be reduced.

Further, in the above-mentioned embodiment, while the through portion 41 of the via 4 has been described as cylindrical, the through portion 41 may be formed in a tapered shape that narrows from the contact portion 42 to the rear side of the semiconductor layer 2. The through portion 41 having a tapered shape can be formed by properly changing the processing conditions of etching, for example, during the period of the first etching step.

As mentioned above, by forming the through portion 41 of the via 4 in a tapered shape that narrows toward the rear side of the semiconductor layer 2 and providing a bump 55 further reduced in size according to the size of the narrowest end portion of the through portion 41, the surface area of the bump 55 on the rear surface of the semiconductor layer 2 can be further reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
an integrated circuit provided on a surface of a semiconductor layer; and
a conductive material embedded into a via that penetrates the semiconductor layer in a thickness direction thereof and is electrically connected to the intergrated circuit,
wherein the conductive material includes a contact portion and a through portion, and the contact portion includes a cross-sectional area in a direction normal to the depth direction of the semiconductor layer that is greater than the cross-sectional area of the through portion in a direction normal to the depth direction of the semiconductor layer.

2. The device according to claim 1, wherein
the integrated circuit comprises a contact pad comprising a metal silicide that contacts the conductive material.

3. The device according to claim 2, wherein
the contact portion is substantially hemispherical.

4. The device according to claim 3, wherein
the semiconductor layer includes an expanded portion that contains the contact portion of the conductive material.

5. The device according to claim 1, wherein
the contact portion is substantially hemispherical.

6. The device according to claim 5, wherein
the semiconductor layer includes an expanded portion that contains the contact portion of the conductive material.

7. The device according to claim 1, wherein
the semiconductor layer includes an expanded portion that contains the contact portion of the conductive material.

8. A semiconductor device comprising:
an integrated circuit provided on a surface of a semiconductor layer, the integrated circuit including a contact pad comprising a metal silicide; and
a via that penetrates the semiconductor layer in a thickness direction thereof and is electrically connected to the contact pad by a conductive material disposed in the via,
wherein the conductive material includes a contact portion and a through portion, and the contact portion includes a cross-sectional area that is greater than a cross-sectional area of the through portion.

9. A method of manufacturing a semiconductor device comprising:
forming an integrated circuit on a surface of a semiconductor layer;
etching a through-hole penetrating the semiconductor layer in a thickness direction extending to the integrated circuit;
forming an expanded portion of the through-hole in the semiconductor layer interfacing with the integrated circuit; and
providing a conductive material in the through-hole and the expanded portion.

10. The method according to claim 9, further comprising:
etching the through-hole under a first condition; and
etching the expanded portion under a second condition that is different than the first condition.

11. The method according to claim 10, further comprising:
forming a contact pad on the integrated circuit that contacts the conductive material in the through-hole.

12. The method according to claim 11, wherein
the contact pad is used as an etching stop when performing the etching of the via.

13. The method according to claim 9, further comprising:
forming a contact pad on the integrated circuit that contacts the conductive material in the through-hole.

14. The method according to claim 13, wherein
the contact pad is used as an etching stop when performing the etching.
